(19) United States
(12) Patent Application Publication
(10) Pub. No.: US 2003/0094962 A1
(43) Pub. Date: May 22, 2003

(54) Dual plane probe card assembly and method of manufacture

(76) Inventors: Reynaldo M. Rincon, Richardson, TX (US); Richard W. Arnold, McKinney, TX (US); Lester Wilson, Sherman, TX (US); Scott W. Mitchell, Plano, TX (US)

Correspondence Address: TEXAS INSTRUMENTS INCORPORATED, P O BOX 655474, M/S 3999, DALLAS, TX, 75265

(21) Appl. No.: 09/992,065

(22) Filed: Nov. 21, 2001

(51) Int. Cl. G01R 31/02

(52) U.S. Cl. 324/754

(57) ABSTRACT

A probe card having multiple planes with continuous metal traces from a high density of small, robust probe contacts to peripheral vias which enable connection to a test head is fabricated using technology from the printed circuit card industry. The card includes a relatively small, centrally located recessed plane having a plurality of probe contacts precisely patterned to mate with chip contacts, an array of continuous conductive traces, the substrate is folded at specific crease locations, and formed upward to a second array of creases at which the substrate is bent to form a raised plane parallel to the first.

Integrated single unit construction, coupled with adaptability for rapid pattern design or changes in conductors readily enables a low inductance probe card, and its low cost, automated method of manufacture is compatible with tight pitch and high performance requirements of integrated circuits both in current production, and those in plans for the future.

### FIELD OF THE INVENTION

This invention relates to testing of integrated circuits, and more particularly to a probe card apparatus for the testing of integrated circuits, and a method for fabricating said apparatus.

### DESCRIPTION OF PRIOR ART

Integrated circuits (ICs) are formed as multiple, identical, discrete chips on a semiconductor crystal wafer. In wafer form, each of the integrated circuit chips is normally tested by a computer operated apparatus to exercise the circuits and verify the electrical functions, using a testing process commonly referred to as multiprobe testing. Individual chips may be tested similarly in a die carrier test device.

Conventional multiprobe testing apparatus includes a plurality of rigid or flexible probe needles to connect the IC device to a substrate having fan out wiring to the test equipment. The substrate, typically a probe card, includes a plurality of electrical leads terminating in conductive needles, which in turn make electrical contact with input/output contacts of the various circuit elements on the integrated circuit chip being tested. Typically the probe card has an opening in the center through which cantilevered needles or blades extend downward to touch pads on the device under test (DUT). The probe card is held in a support ring, and the wafer is placed on the surface of a work holder which is commanded to move in x, y, and z directions by the test equipment, thus allowing the needles to come into contact, and to drive across the pads in order to remove contamination, and allow ohmic contact.

Chip contacts most often are the pads to be electrically connected to the next level of circuitry, and may be referred to as bond pads. Bond pads most often have an aluminum or copper surface, are square or rectangular in shape, and are recessed slightly below the surface of the passivation layer. Multiprobe testers and die carriers have a plurality of contact devices attached to the probe card, and mirror the chip bond pads. The contacts are fanned to the perimeter by an array of conductive traces.

A thin, but tenacious aluminum oxide, as well as other insulating contaminants exist on the surface of aluminum bond pads, requiring that the contaminants be penetrated in order to make good electrical contact for accurately testing the circuits. Similarly, copper is subject to various oxides, some of which are insulating and must be penetrated by the probe in order to be tested accurately.

FIG. 1 illustrates a probe card of known technology wherein a plurality of cantilevered needles 11 or blades are arrayed and attached to conductive traces 12 on an insulating polymeric ring 10. The needles 11 are in contact with bond pads 14 on a semiconductor wafer 15 which is supported on, and moved by the work station platform 13 of a tester.

The needles 11 or probe elements may be secured to the probe card 10 by an adhesive, or they may be bonded, as by welding to a blade. Typically an opening is provided in the center of the ring for the needles to extend through, and for aligning the needles to bond pads 14 on the device 15 to be tested. The card 10 is in electrical contact with a probe head (not shown) of a tester which in turn provides electrical connection to the controlling computer, and which supplies commands for mechanical contact of the needles 11 to bond pads on the chip. Following contact, the work station 13 is then commanded to move horizontally in order to effectively cause the needles 11 to scrub the relatively soft metallic surface of the bond pads 14, and allow ohmic contact to be made.

Probe needles must be accurately positioned in order to assure that each one makes electrical contact with a contact location or bond pad on the integrated circuit. With conventional probe card needles, final positioning is accomplished by bending the needles after they are mounted on the probe card, which is laborious, time consuming, and expensive.

As integrated circuits have become more complex, it is more difficult to establish electrical contact with the chip bond pad metal because pad sizes have decreased, the density of pads has increased, and the distance between pads has decreased. As a result, needles and connections are too large, and have insufficient room to allow a scrubbing motion for the needles to penetrate the oxide. Testing some chips cannot be achieved with conventional needle contacts; in particular, needle testing is nearly impossible for high density bond pads on ICs where the pad pitch is 75 microns or less, and the number of contacts is in the range of 400 or greater per device.

To further complicate testing accuracy, the length of needles, and the number of connections and interfaces between needle tips and the test head has an inductive effect which limits the testing bandwidth, and is a serious impediment for some high speed circuits.

The tight pitch of probe needles, and the angles of their projection necessary for these devices is extremely difficult to manufacture, and in turn ensures a high cost. Further, both delivery and maintenance of such cards adds significantly to testing cycle time.

As a result of these issues, a number of attempts have been made to provide alternate probe card technology. Much of the newer technology centers around photolithographically defined conductor leads on polymeric membranes with plated or spring loaded contact mechanisms. Both die carriers and membrane probe cards usually rely on metallic balls or spheres as the contact mechanism. These approaches must have a means for scraping, and for applying pressure to cause the membrane to make uniform contact across the chip. Particulate matter, such as diamonds or metals have been incorporated in the contact devices in an attempt to penetrate bond pad surface insulators, but these are difficult to control, are subject to incorporation of contamination around and between the particles which interfere with contact. The issue of uniform electrical contact, as well as alignment is further aggravated by thermal expansion of the membrane resulting from a significant amount of heat generated by the chip during the testing procedure.

A number of issues have prevented membrane probe cards from becoming the industry preferred testing contact technology, and not the least of which includes the high cost of fabrication. However, the processes used in membrane cards, i.e., photolithography, etching, and plating do provide a means for conductor uniformity, and allow much more closely spaced conductors, which is becoming increasingly more necessary for testing.

Because of the aforementioned issues with prior probe card technologies, and because of the anticipation of even tighter bond pad pitch on future integrated circuits, it would be very advantageous to the industry to have a reliable, high density, high performance probe card with a low cost, rapid means of fabrication, modification, or repair.

### SUMMARY OF THE INVENTION

It is an object of the current invention to provide a wafer probe assembly suitable for testing integrated circuit chips having a high density of input/output pads.

It is an object of the invention to provide an automated, reproducible method for rapidly and economically manufacturing a high density probe apparatus.

It is an object of the invention that the probe card assembly comprises a printed circuit card substrate, a plurality of continuous conductive traces, and an equal number of very small probe contact devices.

It is an object of the invention to provide a probe card from a single substrate, formed into onto multiple planes having small probe contacts on a recessed centrally located horizontal plane, and conductors in a fanned out pattern on an elevated second plane. The dual plane arrangement provides a means for probes to contact the DUT, and the main body of the assemblage to be supported by a perimeter support ring without interference from each other.

It is an object of the invention to provide a precisely dimensioned probe card having conductive traces on one surface, wherein one end of each conductive trace terminates in a conductive via, and the opposite end terminates at the probe contacts, and further that each conductive trace be formed as a single element having no additional interfaces or joints which contribute to inductance of the conductor.

It is further an object of the invention that the probe contacts are formed as a single element having only one interface to conductors on the card.

It is an object of the invention to provide a probe card wherein dimensions of the conductive traces are readily customized to allow lower inductance levels on selected traces which in turn supports high speed testing.

It is an object of the invention that the conductor designs are readily altered or scaled to meet changes in chip dimensions.

It is yet another object of the invention to provide a robust probe card contact apparatus which minimizes the amount of maintenance required during and after usage.

It is an object of the invention to provide a probe card which is compatible with existing probe heads, and existing tester operation.

Yet another object of the current invention is to provide a reliable, high performance probe card apparatus capable of removing oxides and contamination from chip contact pads while avoiding damage to the probe contacts.

The objectives of this invention are met by forming a probe card having more than one plane with continuous metal traces from the high density probe contacts to peripheral vias which enable connection to the test head. The preferred card includes a relatively small, centrally located recessed plane having a plurality of robust probe contacts precisely patterned to mate with chip contacts, an array of conductive traces one end of which is in intimate contact with the probes, and the substrate is folded at specific crease locations, and formed upward to a second array of creases at which the substrate is bent to form a raised plane parallel to the first. Conductive traces on the card terminate in an array of conductive vias through the rigid substrate and mate with contacts for the connecting test head.

The probe card is fabricated from computer generated inputs to a laser, which in turn fabricates a mask for patterning conductive traces on an insulating substrate. Copper laminated on both major surfaces of the substrate is patterned prior to scoring the substrate at locations which will subsequently be folded to form a recessed plane where probe contacts are located. High resolution, rapid and low cost patterning of conductor traces on the substrate assembly is accomplished using patterning technology well known from the printed circuit industry.

A somewhat flexible film material is disposed between the substrate base and the conductors, thereby supporting the ductile conductive traces, and allowing them to remain continuous when the probe card is scored and folded to form a recessed plane in the center.

On the elevated plane of the card, conductive vias near the perimeter connect the conductor traces through the substrate to terminals on the opposite surface where tester connections are to be made. In some embodiments, that depressed portion of the card which includes the probes is backed by an elastomeric material which makes it possible to apply pressure to the contact probes, to scrub the chip contacts, and return to its original shape when pressure is released.

Probe contacts arranged in the exact pattern of contact pads on the integrated circuit are preferably gold bumps having a precise projection extending from their spherical surface. The bumps are formed by wire bond equipment, wherein each wire is cut leaving a small projection, and the protrusions are subsequently planarized to insure equal height of the projections.

Alternately the probe contacts may be compliant micro probes having a base and needle made of a high tensile and yield strength metal which is inserted into the probe card.

The aforementioned probe interface apparatus, its computer aided design, and automated method of manufacture is compatible with tight pitch and high performance requirements of integrated circuits both in current production, and those planned for the future.

The foregoing and other objectives, features, and advantages will become more apparent from the following detailed description of preferred embodiments of the invention which proceeds with reference to the accompanying drawings.

### BRIEF DESCRIPTION OF THE DRAWINGS

FIG. 1 is a cross section of a probe contact apparatus and a conventional probe card. (Prior art)

FIG. 2 is top view of a quadrant of the probe card of the current invention from the top view.

FIG. 3 is a cross section of the multiple plane probe card of the current invention.

FIG. 4 is a stud bump probe contact.

FIG. 5 is a micro probe contact inserted in a probe card. (Prior art)

FIGS. 6a through 6d demonstrate the process flow in the fabrication of the probe card prior to forming into multiple planes.

FIG. 7 is a top view of the card illustrating the fold locations.

FIG. 8 is a cross section of the multiple plane probe card including elastomeric filling.

### DETAILED DESCRIPTION OF THE INVENTION

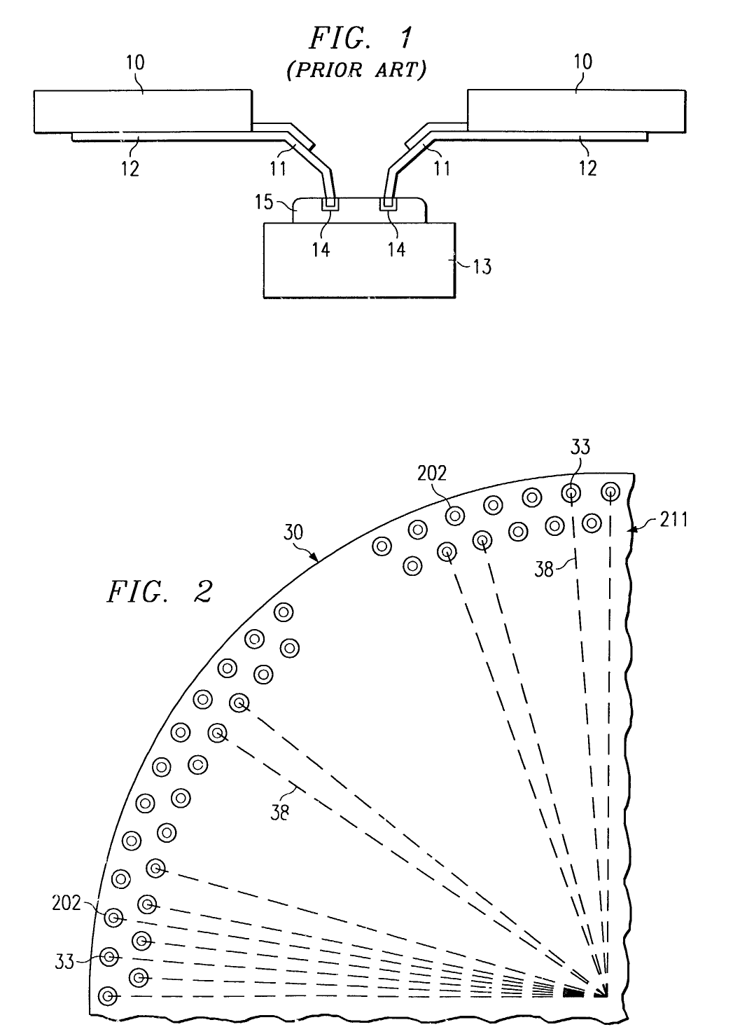

FIG. 2 is a quadrant of the probe card 30 of the current invention from the top view. A plurality of metal contacts 202 to conductive vias 33 is arrayed near the perimeter of the card 30. Dashed lines 38 represent some of the conductive traces on the opposite or first surface of the probe card which terminate in contact with vias 33. The vias 33, in turn, connect to probe head contacts 202 on the second or top surface 211 of the card. The array of contacts 202 will subsequently interface with a probe head of the test equipment (not shown).

From the top view, perimeter probe head contacts 202 are not significantly different from those of conventional probe cards, and by design are compatible with known test heads. However, one difference which can be noted from the view of the second surface is that there are no cantilevered probe needles extending from an opening in the center of the card.

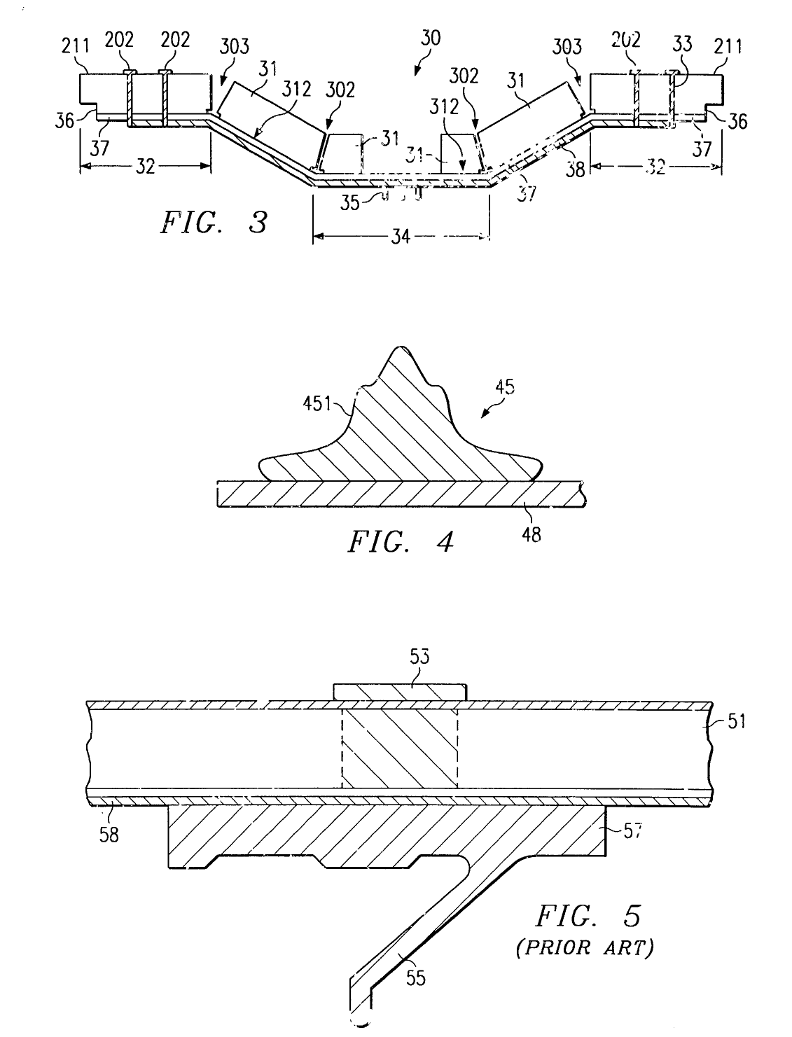

FIG. 3 is a cross section of the probe card assembly 30 which illustrates novel differences between existing technology probe cards (FIG. 1) and the current invention. The assemblage 30 comprises a single circuit board substrate 31 formed into multiple planes, having a plurality of probe contacts 35 protruding from the centrally located first plane 34. The substrate 31 is bent at creases 302, and is formed upward to a second crease 303 where the substrate is reformed into an elevated horizontal plane 32 which is parallel to the first plane 34.

Conductive vias 33 which provide a means for connection to the probe head contacts 202 on the second surface 211 of the card are located near the perimeter of the second plane 32.

The probe card substrate 31 comprises a laminated polymer, such as FR-4, a composite polymer, or other dielectric material typically used in printed circuit or probe card industries. Probe head contacts 202 are copper having a thin protective metal coating which is in intimate electrical contact with copper or solder filled vias 33 through the board.

Probe contacts 35 are small, closely spaced metallic protrusions near the center of the assemblage arrayed to mirror contacts or bond pads on a DUT (device under test).

It can be seen in FIG. 3 that the card has an indention 36 at the edges for positioning the card in a retaining ring (not shown). Because the centrally located plane 34 with probe contacts 35 is positioned below the second or perimeter plane ³², it is possible to use a conventional retaining ring without causing mechanical interference with probe contacts during testing. With known probe cards, needles must extend below the card in order for the retaining ring to avoid interference. However, because the card is shaped into dual planes, there is no such interference to prohibit the probes making contact with chip pads.

A flexible film of adhesive 37 disposed on the first surface 312 of the probe card substrate supports the card at folds or creases 302/303. Conductive traces 38 leading from the probe contacts 35 to conductive vias 33 are affixed to the adhesive.

Probe contacts 35 are preferably “stud bumps” attached to conductive traces 38 near the center of a probe card. FIG. 4 is a more detailed illustration of a stud bump 45, having a tip 451 which facilitates scrubbing of the bond pad, in order to remove contamination. Stud bumps preferably comprise gold, and are attached by a wire bonder to the conductive trace 48. The wire bonder dispenses a gold wire, and by transfer of thermosonic and /or thermal compression energy forms a somewhat spherical bump on the metal surface. The diameter of such bumps is smaller than the chip contact pads. After formation of the ball or bump, a tail of wire extending from the ball is cut to provide a protrusion, such as the tip 451. Such wire bonding technology is well known for interconnecting semiconductor chip pads to conductors on package substrates. Therefore, the technology for providing the required bump size and array configuration on a probe card is a reliable, and practical means for fabricating high density, robust, reliable contacts. The somewhat rigid bumps with protrusions are capable of removing oxides or other contaminants from chip bond pads.

In an alternate embodiment, the probe contact is a micro probe, such as illustrated in FIG. 5. This application is related to application Ser. No. 09/968,963 filed Oct. 2, 2001, and is incorporated herein by reference. The micro probe is a single unit comprising a base 57 and a needle 55 made from a conductive metal wherein the metal has high yield and tensile strength. The base 57 has an extension 53 which is inserted through the probe card 51, and connected electrically to a conductive trace 58. Micro probes are readily fabricated from thin metal structures having spring-like action to provide reliable contacts for repeated use.

The probe contact apparatus of the current invention provides a number of innovative advantages to the semiconductor industry. The novel structure and method of manufacture lead to substantially lower cost and rapid cycle times, necessary to respond to the fast paced introduction of improved chip designs for both new and revised products.

The method for manufacture includes the following process steps. First, a computer generated pattern of the conductors for the probe card, including probe contact geometry and location, and those of conductive traces is input to a laser for mask fabrication. Rapid and economical mask fabrication employs the technology widely used throughout the printed circuit industry, and is not a subject of this invention.

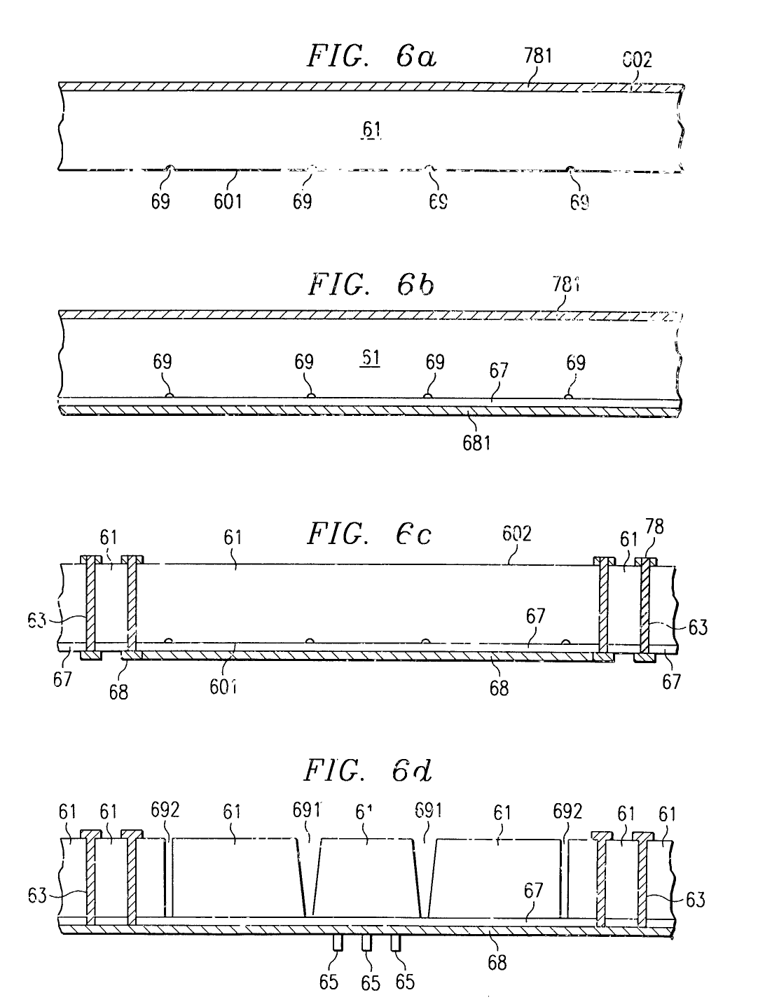

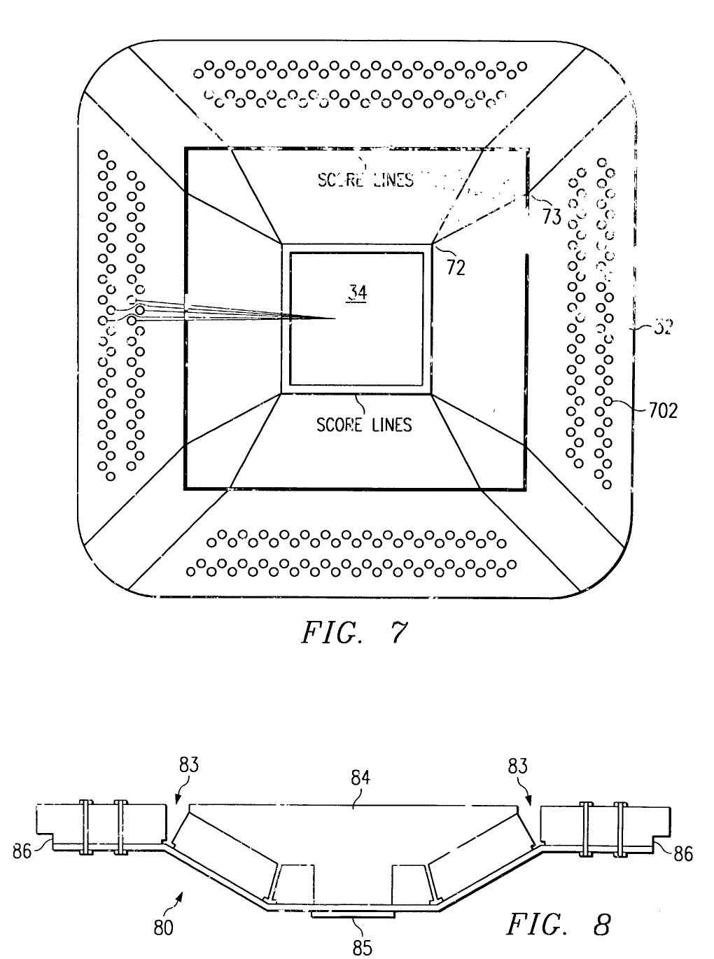

The process flow for fabrication of the probe card prior to forming into multiple planes is shown in FIGS. 6a through 6d. FIGS. 7 and 8 show the final steps in formation of a multiple plane probe card.

A coplanar circuit board substrate 61, preferably comprising a laminate or composite polymer, in the range of 0.005 to 0.040 inches thickness having a copper film 781 laminated onto one surface 602 is scored at predetermined locations 69 on the first surface 601, as illustrated in FIG. 6a. In FIG. 6b, a flexible film of adhesive 67 is disposed on the first major surface 601, and a layer of copper 681 is affixed to the adhesive.

In the next step, illustrated in FIG. 6c, an array of apertures 63 which will subsequently be filled to form conductive vias are drilled near the perimeter of the card. Vias are filled, preferably by plating with copper.

Using technology from the printed circuit industry, the copper layers 681 and 781, shown in FIG. 6b are patterned on each surface. Patterning on the first surface 601 includes an array of conductive traces 68 extending from the array of pads onto which probe devices will be attached to the via locations 63. Patterning on the second surface 602 forms probe head contacts 78 surrounding the terminus of conductive vias 63.

In the following step, as illustrated in FIG. 6d, probe contacts 65 are attached to the conductive traces in the centrally located contact area, preferably by wire bonding to form stud bumps. As an alternate, holes are laser drilled in the contact areas for subsequent attachment of micro probes.

As shown in FIG. 6d, slits 691 and 692 are drilled through the coplanar probe card 61 from the second surface 602 opposite each score mark 69. Slits 691 and 692 extend only through the card substrate, and do not pierce the flexible adhesive 67 or copper traces 68. Following this step, the card is folded at the slits 691 to form a centrally located depressed plane 34 (as shown in FIG. 3) and is bent at slits 692 to form an elevated plane 32.

FIG. 7 is a top view of the probe card illustrating score marks at points 72 and 73 where the card will subsequently be folded to form a multiple plane probe card, having probe contacts on plane 34 and probe head contacts 702 on plane 32.

In FIG. 8, a preferred embodiment of the multiple plane probe card 80 includes an array of stud bump probe contacts 85, an indentation 86 for retaining ring support, and the recessed area between points 83 is filled with an elastomer 84 which permits pressure to be applied so that the probes make intimate contact to scrub the device under test, and to return to original shape after the pressure is removed. In the alternate embodiment, having micro probes, the compliant polymer is not required owing to the spring-like nature of the probes themselves.

The assembled probe card is subsequently connected to a conventional test head, and known test procedures are followed. The probe card of this invention requires no operator retraining, or process changes from those used with existing technology.

High performance embodiments of the probe card include customized conductor patterns wherein the dimensions of the conductive traces provide, or approach a specific impedance level. The fact that each conductive trace comprises a single material having no joints and interfaces affords a low inductance probe card. Further optimization of the impedance can be achieved by providing a ground plane on the second surface. Probe contact elements, either stud bumps or micro probes which comprise a single element requiring only one connecting interface to the conductive traces, further facilitate low inductance test devices.

The multiple plane probe card advantageously is formed from computer designs which are rapidly changed to meet chip and test requirements. The fabrication method is adapted straightforwardly from that widely used in established printed circuit card industry, and the small, but robust and reliable probes are readily assembled by wire bond or by pattern and etch technology. The multi-plane card requires no training or equipment changes from existing needle type probe cards, but offers the advantages of automated design and rapid, low cost fabrication, as well as the high performance facilitated by simple conductors having minimal interfaces.

The invention has been described with reference to specific embodiments, but it is not intended to limit the scope to a particular form set forth, but on the contrary, it is intended to cover alternatives, modifications, and variations which will become apparent to those skilled in the art. It is, therefore, the intention that the appended claims be interpreted as broadly as possible in view of prior art to include all such variations.

What is claimed is:

1- A dual plane probe card apparatus for contacting and testing integrated circuit chips including:
a probe card substrate having first and second major surfaces;
said probe card substrate offset to form a centrally located horizontal plane, a sloped intermediate area, and a peripheral plane parallel to the first horizontal plane;
a plurality of probe contacts arrayed on the first surface of said central plane in a pattern to mirror the contact pads of a DUT;
an array of conductive traces adhered to said first substrate surface by a flexible insulating film wherein the traces fan from the probe contacts to conductive vias on the peripheral plane; and
an array of conductive vias connecting said conductive traces the first surface to probe head contacts on the second surface.

2- A probe card apparatus as in claim 1 wherein the substrate comprises a single structure.

3- A probe card substrate as in claim 1 wherein said probe card comprises a composite polymer.

4- A probe card as in claim 1 wherein said substrate comprises a laminate polymer.

5- A probe card apparatus as in claim 1 wherein each of said conductive traces comprise a continuous copper member.

6- A probe card as in claim 1 wherein said probe contacts comprise gold stud bumps.

7- A probe card apparatus as in claim 1 wherein said probe contacts are micro probes.

8- A probe card apparatus as in claim 1 wherein said conductive vias comprise copper.

9- A probe card apparatus as in claim 1 further including an elastomeric polymer disposed to fill the depressed central area from the second surface.

10- A probe card apparatus as in claim 1 wherein said dimensions of selected conductive traces are optimized for low inductance values.

11- A probe card apparatus as in claim 1 wherein said probe contacts are below the level of the retaining ring.

12- A probe card apparatus as in claim 1 wherein the diameter of probe contacts is smaller than contact pads of the DUT.

13- A method of fabricating a dual plane probe card including the following steps:
providing masks for conductors on two card surfaces from computer aided design,
forming two sets of score marks on the first surface of a rigid, dielectric substrate at specified locations where the substrate will subsequently be folded to form multiple planes,
laminating a layer of adhesive on the first surface of the substrate, and adhering a layer of copper to said adhesive,
laminating a layer of copper to the second surface of said substrate,
drilling apertures through the substrate at selected locations, and plating with copper to form conductive vias,
patterning the copper layer on each surface using said masks to form probe head contacts on the second surface, and conductive traces on the first surface,
ball bonding to form a stud bump at the centrally located terminus of each conductive trace,
slitting the substrate from the second surface opposite each score mark, and
mechanically folding the card at the inner slits to form a central horizontal plane, forming the card upward to the second set of score marks, and forming a second horizontal plane.

14- A method of fabricating a multiple plane probe card as in claim 12 further including filling the centrally located depression with an elastomer.

15- A method of forming a probe card apparatus as in claim 13 wherein said slits are formed through the substrate and do not penetrate the adhesive film.

16- A method of fabricating a multiple plane probe card including the following steps:
providing masks for conductors on both surfaces from computer aided design,
forming two sets of score marks on the first surface of a rigid, dielectric substrate at specified locations where the substrate will subsequently be folded to form multiple planes,
laminating a layer of adhesive on the first surface of the substrate, and adhering a layer of copper to said adhesive,
laminating a layer of copper to the second surface of said substrate,
drilling apertures through the substrate at selected locations, and plating with copper to form conductive vias,
patterning the copper layer on each surface using said masks to form probe head contacts on the second surface, and conductive traces on the first surface,
laser drilling apertures through the substrate for micro probe attachment at the centrally located terminus of each conductive trace,
slitting the substrate from the second surface opposite each score mark,
mechanically folding the card at the inner slits to form a central horizontal plane, forming the card upward to the second set of score marks, and forming a second horizontal plane, and
inserting a micro probe into the laser drilled apertures, electrically and mechanically attaching a micro probe to the inner terminus of conductive traces.
